(19) United States
(12) Patent Application Publication
(10) Pub. No.: US 2012/0241753 A1
(43) Pub. Date: Sep. 27, 2012

(54) SEMICONDUCTOR DEVICE AND METHOD FOR MANUFACTURING SAME

(75) Inventors: Kazuhiro Akiyama, Fukuoka-ken (JP); Hideki Sakurai, Fukuoka-ken (JP)

(73) Assignee: KABUSHIKI KAISHA TOSHIBA, Tokyo (JP)

(21) Appl. No.: 13/308,653

(22) Filed: Dec. 1, 2011

(30) Foreign Application Priority Data
Mar. 24, 2011 (JP) 2011-066651

(51) Int. Cl. H01L 29/20; H01L 21/20

(52) U.S. Cl. 257/76; 438/478; 257/E21.09; 257/E29.089

(57) ABSTRACT

According to an embodiment, a semiconductor device includes a substrate, a nitride layer and a nitride semiconductor layer. The substrate includes an indented structure provided at a major surface. The nitride layer provided entirely on the major surface is at least one of polycrystalline and amorphous, and includes at least one of p-type impurity and n-type impurity. The nitride semiconductor layer is provided on the nitride layer.

### CROSS-REFERENCE TO RELATED APPLICATIONS

This application is based upon and claims the benefit of priority from Japanese Patent Application No. 2011-66651, filed on Mar. 24, 2011; the entire contents of which are incorporated herein by reference.

### FIELD

Embodiments are generally related to a semiconductor device and a method for manufacturing the same.

### BACKGROUND

To improve the characteristics of an LED made of nitride semiconductors, it is important to reduce the dislocation density of the stacked body including the light emitting layer and to improve the flatness of the light emitting layer.

However, the nitride semiconductor is grown on a substrate, such as a sapphire substrate or SiC substrate, having a lattice constant different from that of the nitride semiconductor. Thus, dislocations are likely generated due to the difference in lattice constant between the grown layer and the substrate. It is also difficult to make the surface of the crystal layer uniform.

### BRIEF DESCRIPTION OF THE DRAWINGS

FIGS. 1A and 1B are schematic cross-sectional views illustrating a semiconductor device according to an embodiment;

FIGS. 2A and 2B are schematic sectional views illustrating a growth process of a nitride semiconductor layer according to the embodiment;

FIGS. 3A to 3D are timing charts illustrating a growth sequence of semiconductor layers according to the embodiment;

FIG. 4 is a graph showing numbers of pits at a surface of a GaN layer grown on a buffer layer for a concentration of impurity doped in the low temperature buffer layer;

FIGS. 5A to 5C are schematic cross-sectional views illustrating a shape of the low temperature buffer layer according to the embodiment.

### DETAILED DESCRIPTION

In general, according to an embodiment, a semiconductor device includes a substrate, a nitride layer and a nitride semiconductor layer. The substrate includes an indented structure provided at a major surface. The nitride layer provided entirely on the major surface is at least one of polycrystalline and amorphous, and includes at least one of p-type impurity and n-type impurity. The nitride semiconductor layer is provided on the nitride layer.

Embodiments of the invention will now be described with reference to the drawings. Like portions in the drawings are labeled with like reference numerals, and the different portions are described in the following embodiments, wherein the detailed description of the like portion is omitted as appropriate.

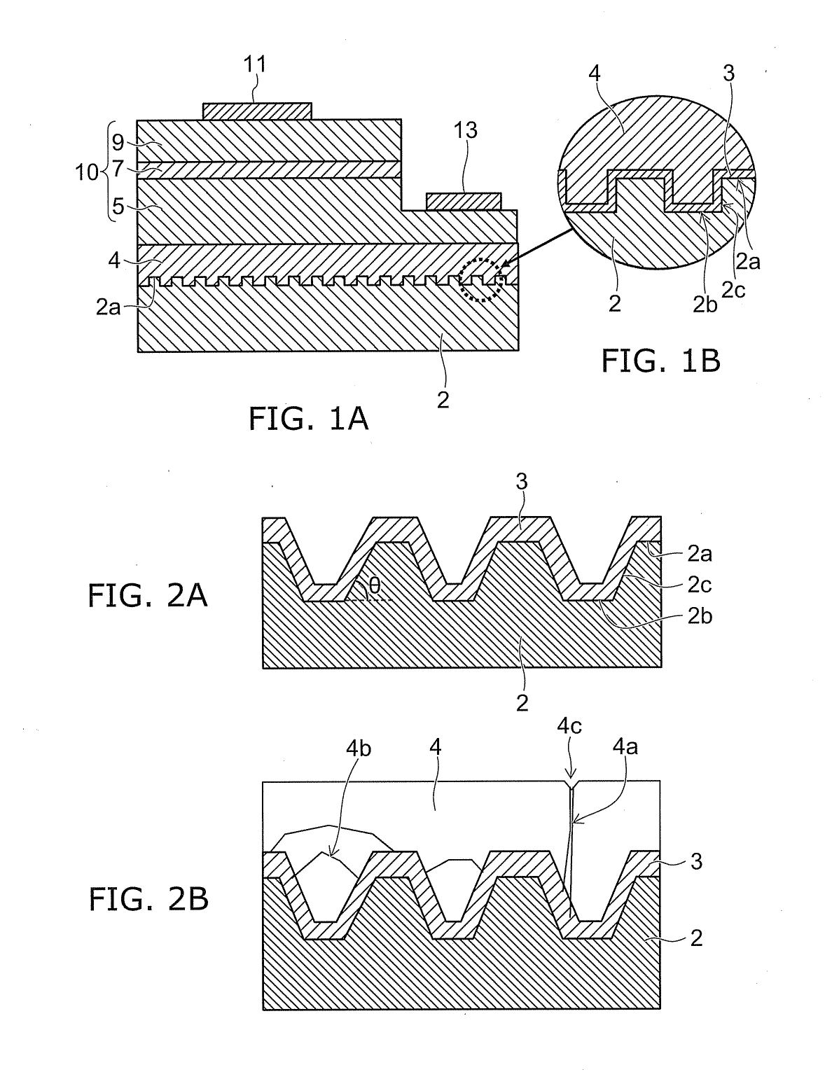

FIGS. 1A and 1B are schematic views showing the cross-sectional structure of a semiconductor device 100 according to an embodiment. FIG. 1A shows the overall cross section of the semiconductor device 100. FIG. 1B shows a partial cross section near the interface between the substrate 2 and the buffer layer 4. The semiconductor device 100 is e.g. a blue LED made of GaN-based nitride semiconductors.

As shown in FIG. 1A, the semiconductor device 100 includes a sapphire substrate 2 and a GaN buffer layer 4. An indented structure having a depth of e.g. several ten nm to several μm is processed at the major surface 2a of the sapphire substrate 2.

As shown in FIG. 1B, a so-called low temperature buffer layer 3 formed at a lower temperature than the GaN buffer layer 4 is provided between the sapphire substrate 2 and the GaN buffer layer 4. The low temperature buffer layer 3 is doped with at least one of p-type impurity and n-type impurity. The low temperature buffer layer 3 includes a nitride layer, which is amorphous or polycrystalline, or a layer in which amorphous and polycrystalline portions are mixed.

Here, the p-type impurity and n-type impurity are the ones that provide p-type and n-type conductivity in the case where the nitride layer is a nitride semiconductor layer.

The indented structure of the sapphire substrate 2 can be provided by e.g. selectively etching the major surface 2a in a configuration including a plurality of protrusions and a continuous bottom surface 2b there around. Alternatively, the indented structure may be provided with a plurality of spaced depressions selectively etched in the major surface 2a.

As shown in FIG. 1B, the low temperature buffer layer 3 is thinner than the height of the protrusion of the indented structure, or the depth of the depression of the indented structure. The low temperature buffer layer 3 is provided so as to uniformly cover the upper surface (major surface) 2a, the side surface 2c and the bottom surface 2b along the shape of the indented structure. The GaN buffer layer 4 is provided on the low temperature buffer layer 3, and a stacked body 10 including an n-type GaN layer 5, a light emitting layer 7, and a p-type GaN layer 9 is provided on the GaN buffer layer 4. Furthermore, a p-electrode 11 is provided on the p-type GaN layer 9, and an n-electrode 13 is provided on the n-type GaN layer 5, which is exposed by mesa-etching the stacked body 10.

The light emitting layer 7 includes e.g. an MQW (multi-quantum well) structure in which a plurality of In_{y}Ga_{1-y}N well layers and GaN barrier layers are stacked. Hence, the semiconductor device 100 can emit, for example, blue light by passing a driving current from the p-electrode 11 to the n-electrode 13.

FIGS. 2A and 2B are schematic sectional views showing the process of a nitride semiconductor layer, which constitutes a part of manufacturing processes of the semiconductor device 100.

As shown in FIG. 2A, the low temperature buffer layer 3 made of a nitride layer can be grown on the major surface 2a of the sapphire substrate 2 by e.g. the MOCVD (metal organic chemical vapor deposition) method.

The indented structure provided at the major surface 2a of the sapphire substrate can be formed by e.g. the RIE (reactive ion etching) method with a resist film used as a mask. The sapphire substrate and the resist film are both etched in RIE. Hence, as shown in FIG. 2A, the side surface 2c of the indented structure is formed in a sloped shape. For instance, by selecting the condition of RIE and the material of the resist film, the slope B of the indented structure can be arbitrarily controlled in the range of 0<θ≦90°. In this embodiment, for instance, B is set to approximately 60°.

The low temperature buffer layer 3 is e.g. a nitride layer including at least one of In, Ga, and Al. The low temperature buffer layer 3 may be made of a nitride having the composition represented by InₓAl_{y}Ga_{1-x-y}N (0≦x, y≦1, 0≦x+y≦1), or a mixture ratio close thereto.

As a raw material of the low temperature buffer layer 3, for instance, it is possible to use a group III gas including at least one or more of trimethylindium (TMI), trimethylgallium (TMG), and trimethylaluminum (TMA), and ammonia gas (NH₃). At the surface of the indented structure of the sapphire substrate 2, chemical reaction including p-type impurity or n-type impurity occurs. This promotes diffusion of the elements In, Ga, Al, and N contained in these raw materials. Thus, a uniform low temperature buffer layer 3 is formed on the upper surface 2a, the bottom surface 2b and the side surface 2c of the indented structure.

For instance, the p-type impurity can be at least one of Mg and Zn, and the n-type impurity can be Si.

As shown in FIG. 2A, the low temperature buffer layer 3 is provided uniformly along the shape of the indented structure. For instance, the thickness of the low temperature buffer layer 3 can be set to 10-80 nm.

The term “uniform” used herein is not limited to the sense that the thickness of the low temperature buffer layer 3 formed along the indented structure is constant. It refers to the state in which the thickness of the low temperature buffer layer 3 is not extremely varied on the upper surface 2a, the bottom surface 2b, and the side surface 2c of the indented structure. For instance, among the portions formed on the upper surface 2a, the side surface 2c, and the bottom surface 2b on one protrusion, the variation in thickness lies within 30% with reference to the thickest portion.

Next, as shown in FIG. 2B, a GaN buffer layer 4 made of a nitride semiconductor layer is grown on the low temperature buffer layer 3.

The GaN buffer layer 4 is provided so as to bury the indented structure of the sapphire substrate 2 to form a flat surface. The thickness of the GaN buffer layer 4 can be set to e.g. 1-5 μm.

As shown in FIGS. 2A and 2B, a threading dislocation 4a extends in the GaN buffer layer 4 from the low temperature buffer layer 3 to the surface, and dislocations 4b starting from the surface of the low temperature buffer layer 3 are connected inside the GaN buffer layer. Such dislocations can be observed by using a SEM (scanning electron microscope) or TEM (transmission electron microscope).

The threading dislocation 4a appears as a pit 4c at the surface of the GaN buffer layer 4. The pit 4c serves as the starting point of a dislocation generated inside the stacked body 10 on the GaN buffer layer 4. On the other hand, the internally connected dislocation 4b does not appear at the surface, but leaves the surface of the GaN buffer layer 4 free from crystal defects. That is, decreasing the threading dislocations 4a may reduce the dislocations of the stacked body 10 on the GaN buffer layer 4.

As described above, the low temperature buffer layer 3 is amorphous or polycrystalline, or a layer in which amorphous and polycrystalline portions are mixed. Thus, the low temperature buffer layer 3 has no fixed plane orientation. Furthermore, by impurity doping, the low temperature buffer layer 3 includes a composition such as MgGaN. Thus, when the GaN buffer layer 4, for instance, is formed on the low temperature buffer layer 3 overlying uniformly along the shape of the indented structure, the so-called lateral growth becomes dominant. In the lateral growth, the GaN growth is promoted horizontally from the side surface 2c of the indented structure.

More specifically, in the early phase of the growth of the GaN buffer layer 4, GaN grows horizontally from the side surface 2c of the indented structure and buries the indented structure. Subsequently, the GaN layer grows upward. As a result, dislocations extending horizontally from the adjacent side surfaces of the indented structure are merged with each other to form a dislocation 4b in the early phase of the growth, as shown in FIG. 2B. Hence, when GaN grows upward, dislocations due to lattice mismatch between the sapphire substrate 2 and GaN decrease. Thus, threading dislocations 4a reaching the surface of the GaN buffer layer 4 can be decreased.

Furthermore, impurity-containing compounds such as MgGaN may relax the lattice mismatch, and thereby it becomes possible to reduce dislocations in the early phase of the growth. Thus, the decrease of pits 4c corresponding to threading dislocations 4a may reduce the dislocations of the stacked body 10 formed on the GaN buffer layer 4.

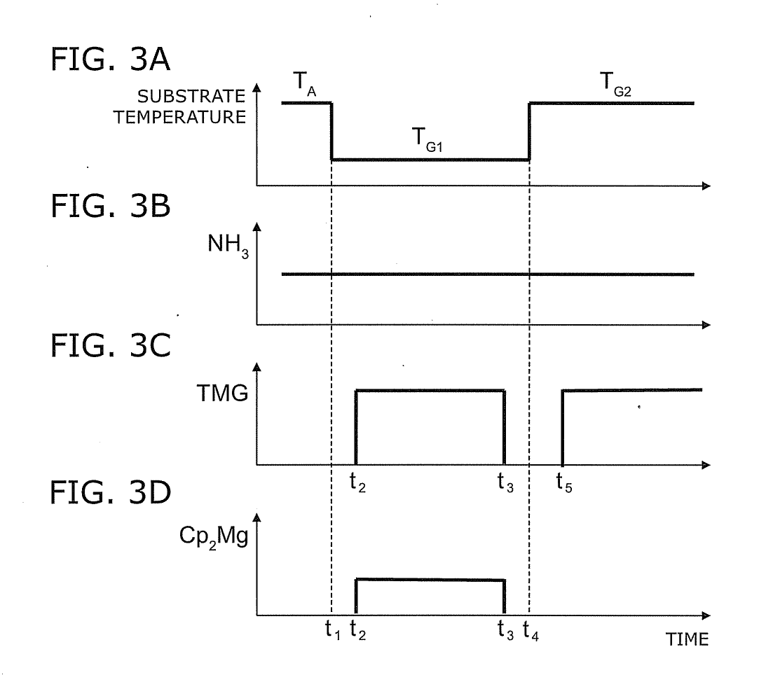

FIGS. 3A to 3D are timing charts illustrating the growth sequence of semiconductor layers according to the embodiment. FIGS. 3A to 3D show an example of forming a low temperature GaN layer as a low temperature buffer layer 3 on the sapphire substrate 2 and forming a GaN buffer layer 4 on the low temperature buffer layer 3. In FIG. 3A, the horizontal axis represents time, and the vertical axis represents substrate temperature. FIGS. 3B and 3C are timing charts in which the vertical axis represents the flow rate of NH₃ and TMG, respectively. FIG. 3D is a timing chart in which the vertical axis represents the flow rate of doping gas Cp₂Mg (bis cyclopentadienyl magnesium).

As shown in FIG. 3A, the sapphire substrate 2 is heated to a temperature T_{H} of e.g. 1000-1200° C. and is heat-treated in a hydrogen atmosphere for cleaning the surface of the sapphire substrate 2. Next, the temperature of the sapphire substrate 2 is cooled to the temperature T_{G1} for forming the low temperature buffer layer 3 (t=t₁). After completing the formation of the low temperature buffer layer 3, the sapphire substrate 2 is heated to the temperature T_{G2} for forming the GaN buffer layer 4, i.e., high temperature buffer layer (t=t₄). For instance, T_{G1} can be set in the range of 400-700° C., and T_{G2} can be set in the range of 700-1200° C.

As shown in FIG. 3B, while the temperature of the sapphire substrate 2 is controlled by the above temperature cycle, NH₃ is supplied at a constant flow rate.

First, after the sapphire substrate 2 is heat-treated, the sapphire substrate 2 is cooled to the temperature T_{G1} for forming the low temperature buffer layer (t=t₁). Then, as shown in FIGS. 3C and 3D, TMG and doping gas Cp₂Mg are supplied at a prescribed flow rate for a prescribed time (t₂-t₃). Thus, TMG is reacted with NH₃ at the surface of the sapphire substrate 2 to form a low temperature GaN layer doped with p-type impurity Mg.

Next, TMG and Cp₂Mg in the reaction chamber are evacuated for a given time interval (t₃-t₅). During this time, the sapphire substrate 2 is heated to T_{G2} (t=t₄). Then, as shown in FIG. 3D, TMG is supplied and reacted with NH₃ (t=t₅). Thus, a GaN buffer layer 4 can be formed on the low temperature buffer layer 3 (low temperature GaN layer).

For instance, on the sapphire substrate 2 with the slope θ of the side surface of the indented structure being 60°, a low temperature buffer layer 3 having a thickness of 40 nm is formed with T_{H}=1200° C. and T_{G1}=600° C. Then, under the condition of T_{G2}=1200° C., a Mg-doped GaN buffer layer 4 is formed to be approximately 5 μm.

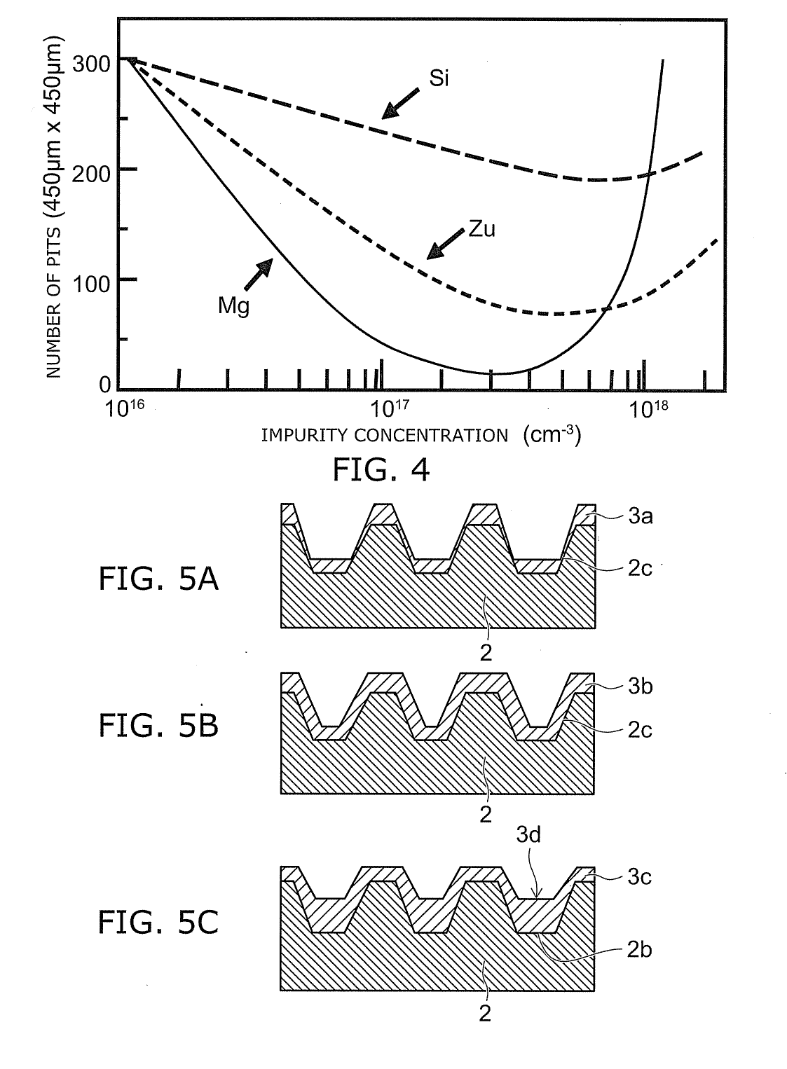

FIG. 4 is a graph illustrating the concentration of impurity doped in the low temperature buffer layer 3 and the number of pits at the surface of the GaN buffer layer 4.

FIG. 4 shows the cases of doping Mg and Zn as p-type impurity and the case of doping Si as n-type impurity. In any of these cases, the number of pits at the surface of the GaN buffer layer 4 has a minimum. With the increase of impurity concentration, the number of pits tends to decrease to the minimum and then to increase. That is, the impurity concentration can be optimized to reduce the number of pits at the surface of the GaN buffer layer 4. For instance, in the case of doping Mg, setting the concentration to 1−6×10¹⁷ cm⁻³ may reduce the number of pits of the GaN buffer layer 4.

FIGS. 5A to 5C are schematic sectional views showing the shape of the low temperature buffer layer 3 formed on the sapphire substrate 2. FIG. 5A corresponds to the state of low impurity concentration in which the number of pits decreases in FIG. 4. FIG. 5B corresponds to the state in which the number of pits is minimized. FIG. 5C corresponds to the state in which the impurity is further doped to a higher concentration.

As shown in FIG. 5A, the thickness of the low temperature buffer 3a on the side surface 2c of the indented structure of the sapphire substrate 2 is thinned in the case of low impurity concentration. Thus, growth from the upper surface 2a and the bottom surface 2b, where the low temperature buffer layer 3a is thick, becomes dominant. Hence, the number of dislocations 4b formed by lateral growth is small, and the number of threading dislocations 4a remains large. As shown in FIG. 5B, in the state in which the number of pits is minimized, a uniform low temperature buffer layer 3b is formed along the shape of the indented structure. Thus, lateral growth becomes dominant, and threading dislocations 4a are minimized.

On the other hand, as shown in FIG. 5C, if the impurity is doped at higher concentration, the low temperature buffer layer 3c is formed thickly on the bottom surface 2b of the indented structure. Thus, the depth of the indented structure is made shallow. This presumably decreases dislocations 4b formed by lateral growth and increases threading dislocations 4a toward the surface of the GaN buffer layer 4.

Thus, the shape of the low temperature buffer layer 3 varies, depending on the doped impurity concentration. The number of pits generated in the surface of the GaN buffer layer 4 varies accordingly. In other words, as shown in FIGS. 5A to 5C, the amount of doped impurity may control the shape of the low temperature buffer layer formed on the indented structure. Thus, adjusting the amount of impurity doped in the low temperature buffer layer 3 may reduce dislocations of the nitride semiconductor layer formed thereon.

Furthermore, according to the embodiment, in addition to the reduction of the number of pits, the flatness of the surface of the GaN buffer layer 4 can be improved. That is, lateral growth buries the indented structure in the early phase of the growth. Subsequently, the GaN buffer layer 4 is formed upward on the flattened surface. Furthermore, decreasing the threading dislocations may improve the flatness of the surface, i.e. surface morphology.

Thus, the characteristics of the semiconductor device 100 (LED) including a stacked body 10 formed on the GaN buffer layer 4 can be improved. For instance, the optical output can be increased, and the emission wavelength distribution in the substrate plane can be improved.

The above embodiment has been described by taking an LED as an example of the semiconductor device. However, the embodiment of the invention is not limited to LEDs, but is also applicable to semiconductor devices such as semiconductor lasers and electronic devices. The growth of nitride semiconductors according to this embodiment is not limited to the MOCVD method. It is also possible to use e.g. the MBE (molecular beam epitaxy) method or the HVPE (hydride vapor phase epitaxy) method.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

The “nitride semiconductor” referred to herein includes group III-V compound semiconductors of BₓIn_{y}Al_{z}Ga_{1-x-y-z}N (0≦x≦1, 0≦y≦1, 0≦x+y+z≦1), and also includes mixed crystals containing a group V element besides N (nitrogen), such as phosphorus (P) and arsenic (As). Furthermore, the “nitride semiconductor” also includes those further containing various elements added to control various material properties such as conductivity type, and those further containing various unintended elements.

What is claimed is:

1. A semiconductor device comprising:
a substrate including an indented structure provided at a major surface;
a nitride layer provided entirely on the major surface being at least one of polycrystalline and amorphous, and including at least one of p-type impurity and n-type impurity; and
a nitride semiconductor layer provided on the nitride layer.

2. The device according to claim 1, wherein the nitride layer is provided uniformly along shape of the indented structure.

3. The device according to claim 1, wherein the nitride layer includes at least one of Al, In, and Ga.

4. The device according to claim 1, wherein
the p-type impurity doped in the nitride layer is at least one of Mg and Zn, and
the n-type impurity doped in the nitride layer is Si.

5. The device according to claim 1, wherein the nitride layer includes a nitride having a composition represented by InₓAl_{y}Ga_{1-x-y}N (0≦x≦1, 0≦y≦1, 0≦x+y≦1).

6. The device according to claim 5, wherein the nitride layer includes GaN doped with Mg.

7. The device according to claim 6, wherein concentration of Mg doped in the GaN is 1×10¹⁷ cm⁻³ or more and 6×10¹⁷ cm⁻³ or less.

8. The device according to claim 1, wherein
the indented structure includes a plurality of protrusions and a bottom surface therearound, and
thickness of the nitride layer is thinner than height of the protrusion.

9. The device according to claim 1, wherein
the indented structure includes a plurality of depressions provided at the major surface, and
thickness of the nitride layer is thinner than depth of the depression.

10. The device according to claim 1, wherein the indented structure includes a side surface sloped with respect to the major surface.

11. The device according to claim 1, wherein thickness of the nitride layer is 10 nm or more and 80 nm or less.

12. The device according to claim 1, wherein the nitride layer includes a mixed portion of polycrystalline and amorphous.

13. The device according to claim 1, further comprising:
a stacked body including a light emitting layer provided on the nitride semiconductor layer.

14. The device according to claim 1, wherein the nitride semiconductor layer includes GaN.

15. A method for manufacturing a semiconductor device comprising:
forming a nitride layer entirely on a major surface of a substrate, an indented structure being provided at the major surface, and the nitride layer including at least one of p-type impurity and n-type impurity; and
forming a nitride semiconductor layer on the nitride layer at a higher temperature than the nitride layer.

16. The method according to claim 15, wherein amount of impurity included in the nitride layer is set to an amount such that the nitride layer is formed uniformly along shape of the indented structure.

17. The method according to claim 15, wherein the nitride layer is formed at 400° C. or more and 700° C. or less.

18. The method according to claim 15, wherein the substrate is a sapphire substrate, and the substrate is heat treated at a temperature of 1000° C. or more and 1200° C. or less in an atmosphere containing ammonia before forming the nitride layer.

19. The method according to claim 15, wherein ammonia and at least one of trimethylindium, trimethylgallium and trimethylaluminum are used as raw materials for forming the nitride layer.

20. The method according to claim 15, wherein concentration of Mg included in the nitride layer is 1×10¹⁷ cm⁻³ or more and 6×10¹⁷ cm⁻³ or less.
